(19) United States
(12) Patent Application Publication
(10) Pub. No.: US 2011/0230028 A1
(43) Pub. Date: Sep. 22, 2011

(54) MANUFACTURING METHOD OF STRAIGHT WORD LINE NOR TYPE FLASH MEMORY ARRAY

(75) Inventors: Yider Wu, Chu-Pei City (TW); Hung-Wei Chen, Chu-Pei City (TW)

(73) Assignee: EON SILICON SOLUTION INC.

(21) Appl. No.: 12/728,348

(22) Filed: Mar. 22, 2010

(51) Int. Cl. H01L 21/8234

(52) U.S. Cl. 438/287; 257/E21.619

(57) ABSTRACT

In a manufacturing method of a straight word line NOR flash memory array, a source line is implanted after the formation of a word line in the NOR type flash memory array is completed, and a discrete implant region is formed in the NOR type flash memory array and parallel to a component isolation structure, and each discrete implant region constitutes an electric connection with a low impedance between a source line and source contacts on the source line. With such discrete distribution, adjacent memory cells will not be short-circuited or failed even if a deviation of a mash occurs during the manufacturing process.

### FIELD OF THE INVENTION

The present invention relates to a manufacturing method of a flash memory array, in particular to a manufacturing method of a straight word line NOR type flash memory array.

### BACKGROUND OF THE INVENTION

In a NOR flash memory, each storage cell is similar to a standard metal oxide semiconductor field effect transistor (MOSFET). Unlike a traditional MOSFET, the flash memory has two gates, and the two gates are stacked with one another to form a gate stack. In addition, the gate disposed at the top of the gate stack is called a control gate which is operated in the same way as a general MOSFET, and the gate disposed at the bottom of the gate stack is called a floating gate which is installed independently between the control gate and the MOSFET. A flash memory can save data by limiting electric charges in the floating gate by the control gate to achieve the purpose of saving data.

With reference to FIG. 1 for a structure of a conventional flash memory array, a contact via is formed separately at positions of a plurality of source contacts 102. Due to limitations of the present existing photolithography, a space for containing each of the source contacts 102 disposed on a source line 108 is greater than the space of a related common source line 104 in order to contain the source contacts 102. Therefore, it is necessary for the common source line 104 to widen the regions around the source contacts 102 to accommodate the source contacts 102. In the manufacturing process, word lines 106 on both sides of each source contact 102 must be curved to increase the regions for accommodating the source contacts. However, the curved word lines 106 will restrict the overall size of a flash memory array 100, and thus the integrated density of the flash memory cannot be improved. In addition, the curved regions of the aforementioned word lines 106 will affect the uniformity of each memory cell in the whole flash memory array 100.

In U.S. Pat. No. 7,488,657, a flash memory array having straight word lines was taught to overcome the aforementioned problems, and its structure as shown in FIG. 2 comprises a source contact 202 formed on a drain line 210. Since the drain line 210 is provided for containing a drain contact D, therefore the drain line 210 (also refer to the drain line 110 as shown in FIG. 1) has a width greater than a common source line 204. With the aforementioned method, the original curved word line 106 (as shown in FIG. 1) can be changed to a straight word line 206 (as shown in FIG. 2). In addition to the foregoing steps, a row of dopants is implanted on the source line 208 at the position of the source contact 202 to overcome the electrical resistance between the common source line 204 and the source contact 202, so that the source contact 202 remains electrically coupled to the common source line 204 after the source contact 202 changes its position. In the foregoing manufacturing process, the dopants must be implanted on the source line 208 precisely. However, it is very difficult to control a precise implantation in an actual operation, and slits of a mask are aligned precisely with the desired implanting regions. Once a deviation occurs, the memory cells may become short-circuited and malfunctioned, since the drain contact D situated in the drain region may be electrically coupled to the common source line 204 situated in the source region by the deviated implant region during the aforementioned conventional manufacturing method. Another cause of this phenomenon resides on the source line. In addition, the manufacturing process adopts an implantation of a high aspect ratio, and the dopant is implant into the whole source line 208 through the floating gate and the tunnel oxide layer easily. Once a deviation of the mask occurs, and the mask is not alight precisely and correctly to the implant region, the non-uniform resistance of the source will increase the probability of short circuits and failure of the memory cells significantly.

### SUMMARY OF THE INVENTION

Therefore, an objective of the present invention is to provide a method of manufacturing a straight word line NOR type flash memory array to enhance the integrated density and the uniformity of the NOR type flash memory array.

Another objective of the present invention is to provide a method of manufacturing a straight word line NOR type flash memory array to relax the precision requirement of aligning a mask for implanting a source line, so as to simplify the manufacturing process and improving the yield rate.

To achieve the foregoing and other objectives, the present invention discloses a manufacturing method of a straight word line NOR type flash memory array applied to a substrate, and the method comprises the steps of: forming a plurality of isolation structures parallel to each other on the substrate; forming a plurality of gate stack structures parallel to each other on the substrate and perpendicular to the isolation structures; forming a plurality of top-cover layers on each gate stack structure separately to define a plurality of straight word lines; forming a plurality of source lines and a plurality of drain lines in a substrate between adjacent gate stack structures, wherein the source lines and the drain lines are parallel to the gate stack structures, and the source lines and the drain lines are arranged alternately between the gate stack structures, and each source line includes a plurality of source doped regions disposed between the isolation structures, and each drain line includes a plurality of drain doped regions disposed between the isolation structures; using a mask to form a plurality of discrete implant regions in the substrate and parallel to the isolation structures by a source line implant process, wherein each discrete implant region at least covers the source line; forming a plurality of spacers on a sidewall of each gate stack structure; forming a plurality of drain lines between adjacent spacers of each drain line; and forming a plurality of drain contacts and at least one source contact on each drain line, wherein the contacts are isolated from each other.

In the step of performing the source line implant in accordance with a preferred embodiment of the present invention, a combination of implant angles)(0°˜30° is used for achieving a resistance value with a high uniformity. The dosage used for the implant is approximately equal to 3×10¹⁴˜1×10¹⁶, 3E14-1E16, (ion/cm²), and the energy is approximately equal to 5˜60(Kev), and the ions used in the source line implant method are arsenic (As) and/or phosphorus (P) ions.

In the step of arranging the mask and carrying out the source line implant in accordance with another preferred embodiment of the present invention, each discrete implant region covers the region between two adjacent source contacts in the substrate. After the step of arranging the mask and carrying out the source line implant takes place, the manufacturing method further comprises a step of performing an over-erase process to every source contact. In the step of carrying out the source line implant, if the implant angle is equal to 0°, the dosage used for the implant is approximately equal to 3×10¹⁴˜5×10¹⁵, 3E14-5E15, (ion/cm²), and the energy is approximately equal to 5˜25(Kev). The ions used in the source line implant method are arsenic (As) and/or phosphorus (P) ions. If the implant angle is 20°˜30°, the dosage used for the implant is approximately equal to 5×10¹⁴˜8×10¹⁵, 5E14-8E15, (ion/cm²), and the energy is approximately equal to 30˜55(Kev). The ions used in the source line implant method are arsenic (As) and/or phosphorus (P) ions. In addition, a combination of implant angles can be used for performing the source line implant.

Therefore, the manufacturing method of the present invention carries out the source line implant after the gate stack structure of the NOR type flash memory array is completed, and the implant regions are discretely distributed. Even if there is a deviation of the mask, the adjacent memory cells will not be short-circuited or failed easily. In addition, the manufacturing method of the invention does not require a high-precision alignment of the prior art.

### BRIEF DESCRIPTION OF THE DRAWINGS

FIG. 1 is a schematic diagram of a structure of a conventional NOR flash memory;

FIG. 2 is a schematic diagram of a structure of another conventional NOR flash memory;

FIG. 3 is a flow chart of a manufacturing method of a straight word line NOR type flash memory array in accordance with a preferred embodiment of the present invention;

FIGS. 4A and 4B are schematic perspective views, showing portions of a straight word line NOR type flash memory array at different steps in accordance with a preferred embodiment of the present invention;

FIG. 5A is a top view of a straight word line NOR type flash memory array in accordance with a preferred embodiment of the present invention;

FIG. 5B is a cross-sectional view of Section A-A′ of FIG. 5A;

FIG. 5C is a cross-sectional view of Section B-B′ of FIG. 5A;

FIG. 6A is a top view of a straight word line NOR type flash memory array in accordance with another preferred embodiment of the present invention;

FIG. 6B is a cross-sectional view of Section A-A′ of FIG. 6A; and

FIG. 6C is a cross-sectional view of Section B-B′ of FIG. 6A.

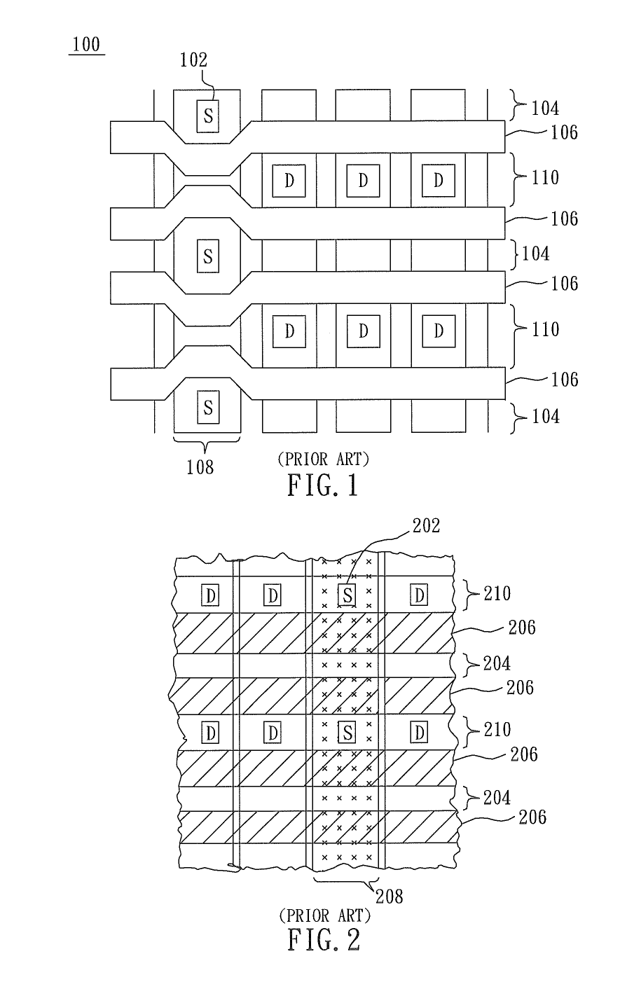

### DESCRIPTION OF THE PREFERRED EMBODIMENTS

The objects, characteristics and effects of the present invention will become apparent with the detailed descriptions of the preferred embodiment and the illustrations of related drawings as follows.

A source line is electrically coupled between a source contact and a source line with a low impedance by a discrete implant method of the present invention, and an implant process takes place after the formation of word lines in the NOR type flash memory array is finished, and the manufacturing method of the present invention is suitable for manufacturing n-channel or p-channel flash memories.

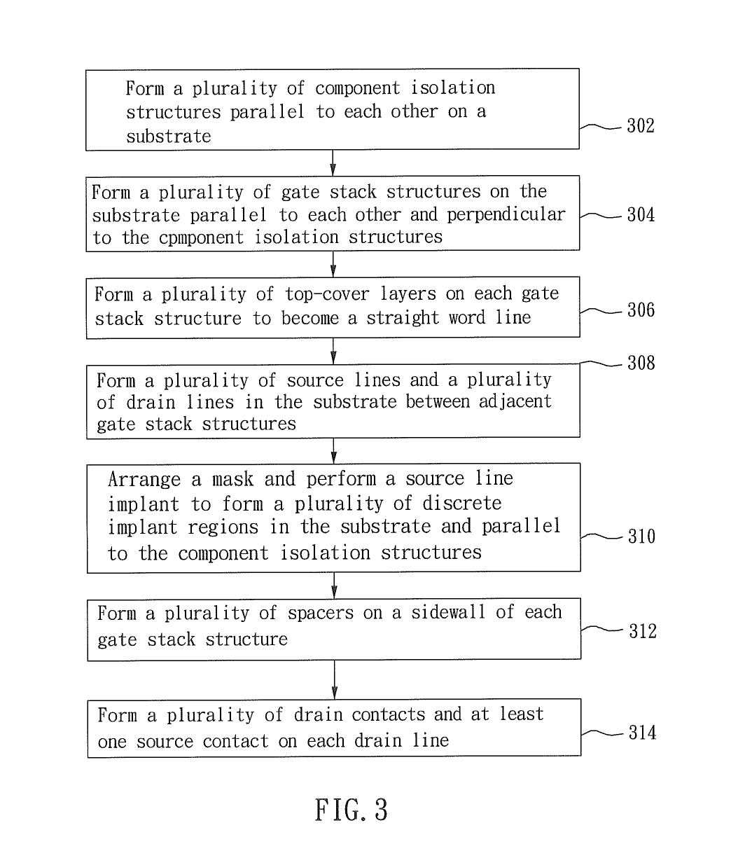

With reference to FIG. 3 for a flow chart of a manufacturing method of a straight word line NOR type flash memory array in accordance with a preferred embodiment of the present invention, the manufacturing method is applied to a substrate. In Step 302, a plurality of isolation structures are formed parallel to each other on a substrate and divided into a plurality of rows, wherein options of the substrate include a silicon substrate, a SiGe substrate, a silicon on insulator (SOI), a silicon germanium on insulator (SGOI) or a germanium on insulator (GOI) and the substrate of this preferred embodiment is a silicon substrate.

In Step 304, a plurality of gate stack structures are formed on the substrate parallel to each other and perpendicular to the isolation structures. In Step 306, a plurality of top-cover layers are formed on each gate stack structure to define a straight word line. In Step 308, a plurality of source lines and a plurality of drain lines are formed in the substrate between adjacent gate stack structures, wherein the source lines and the drain lines are parallel to the gate stack structures, and the source lines and the drain lines are arranged alternately between the gate stack structures, and each source line has a plurality of source doped regions disposed between the isolation structures, and each drain line has a plurality of drain doped regions disposed between the isolation structures. In Step 310, a mask is arranged for performing a source line implant to form a plurality of discrete implant regions in the substrate and parallel to the isolation structures, wherein each discrete implant region at least covers the source line. In Step 312, a plurality of spacers are formed on a sidewall of each gate stack structure. In Step 314, a plurality of drain contacts and at least one source contact are formed on each drain line, wherein the contacts are isolated from one another. The present invention connects two source contacts of two memory units with a low threshold voltage in parallel, such that low impedance occurs between the source contact and the source line of each memory unit.

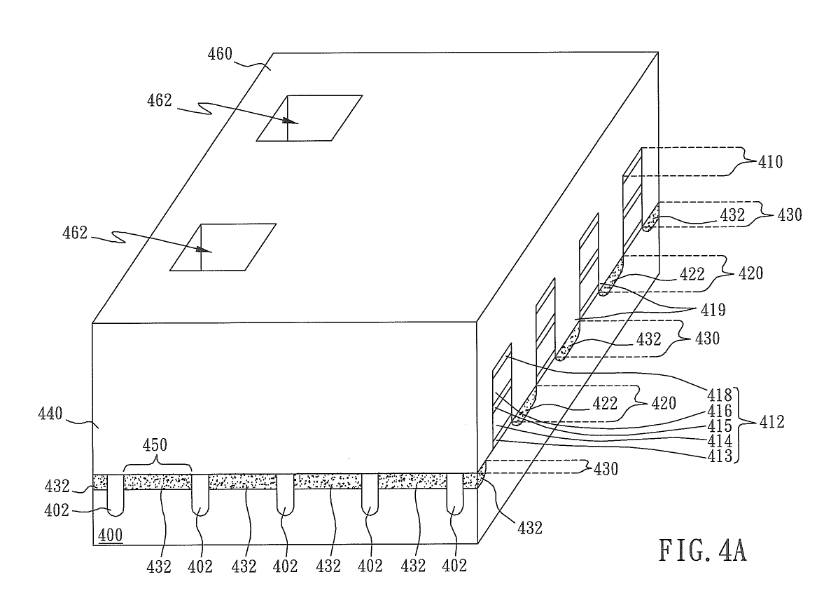

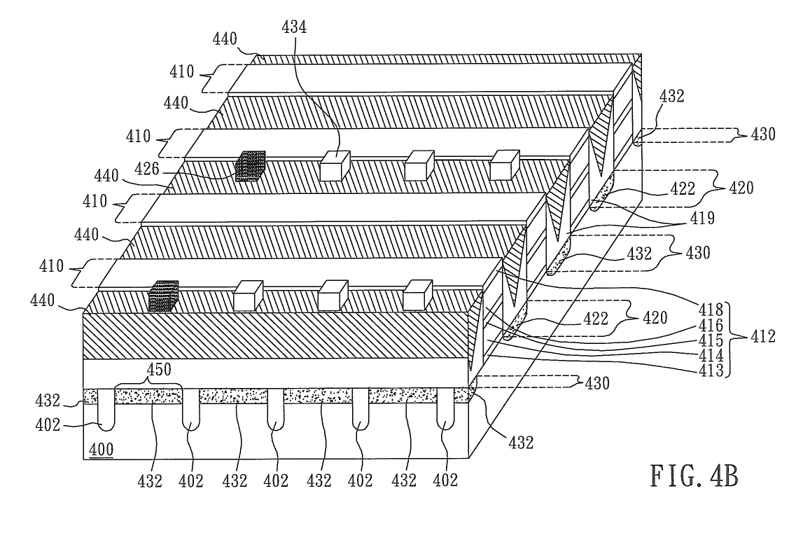

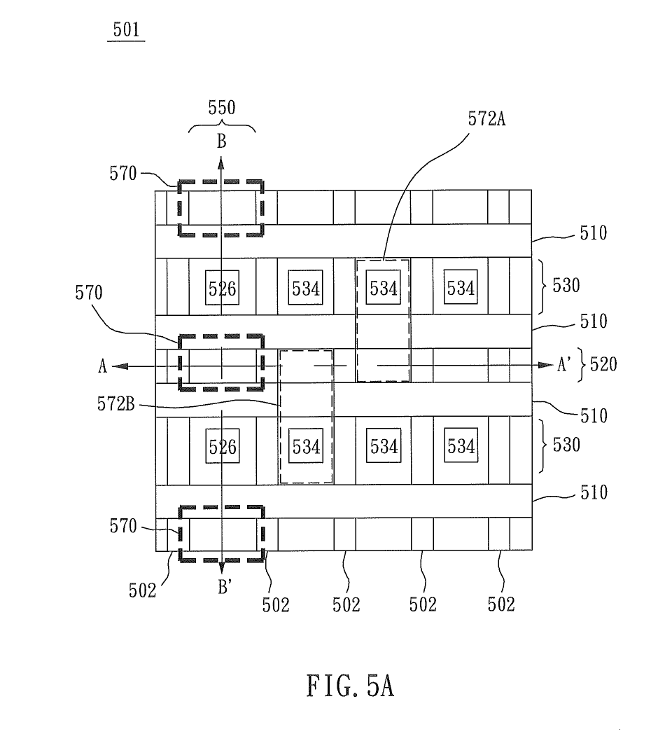

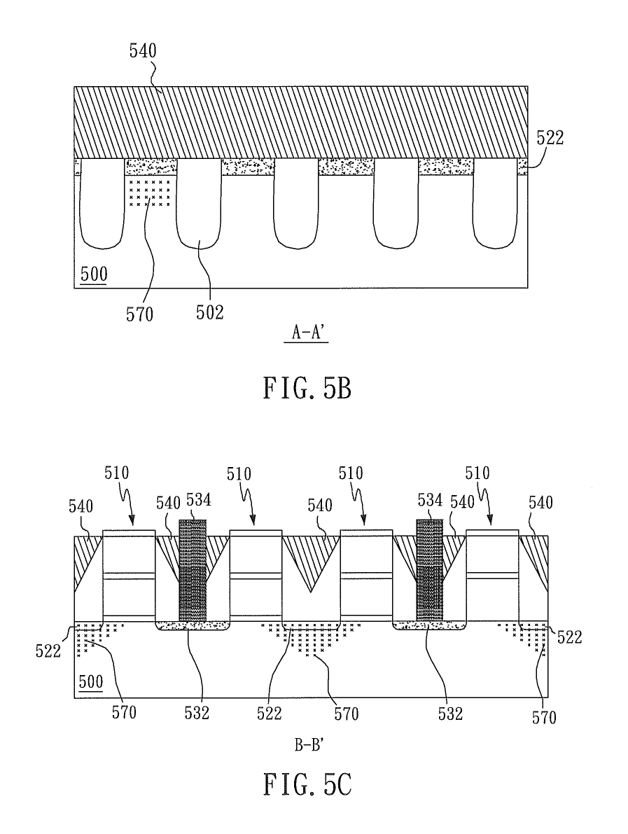

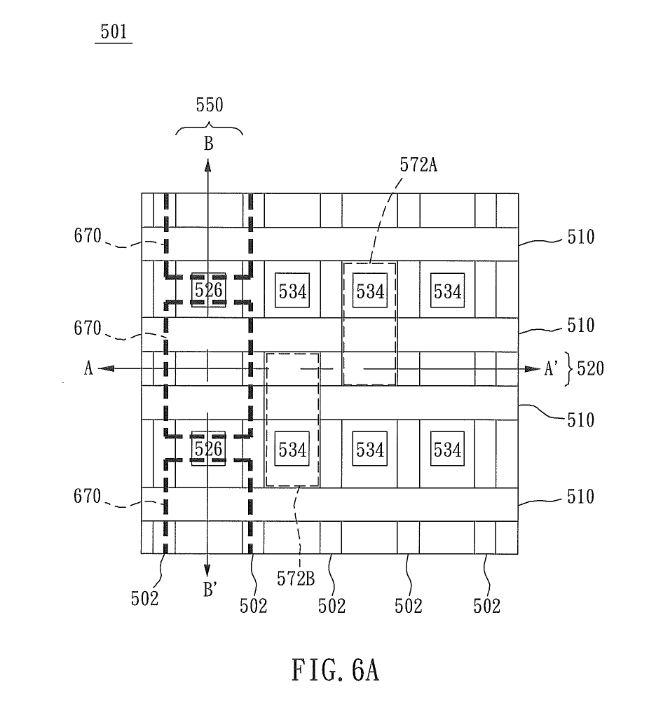

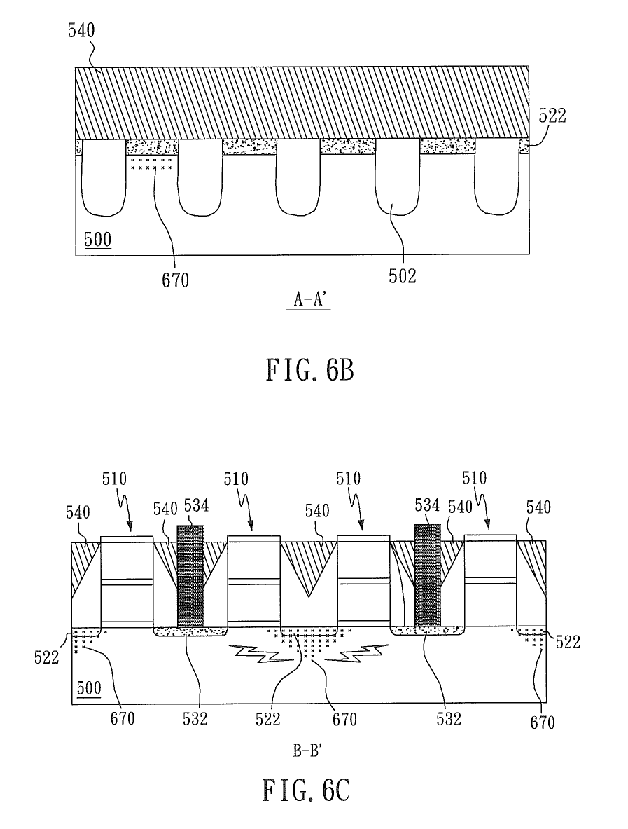

With reference to FIGS. 4A and 4B for schematic perspective views, showing portions of a straight word line NOR type flash memory array at different steps in accordance with a preferred embodiment of the present invention, FIG. 4A illustrates Step 310, wherein a mask 460 is arranged for performing a source line implant, and the mask 460 has a row of discrete openings 462, and a plurality of discrete implant regions 570, 670 (as shown in FIGS. 5 and 6) in the substrate 400 and parallel to the isolation structures 402, such that the row of source contacts 426 becomes a source line (as indicated by 450 of FIGS. 4B and 550 of FIG. 5).

In this preferred embodiment, a substrate 400 includes a plurality of isolation structures 402 parallel to each other and formed on the substrate 400, wherein the isolation structures 402 can be field oxide layers, shallow trench isolation (STI) structures, or any isolation structure with an insulation effect, and the component isolation structure 402 is a shallow trench isolation (STI) structure in this preferred embodiment. The substrate 400 further includes a plurality of gate stack structures 412 parallel to each other, and each gate stack structure 412 includes a tunnel oxide layer 413, a floating gate 414, a dielectric layer 415, a control gate 416, and each gate stack structure 412 further includes a top-cover layer 418 provided for forming a word line 410. The manufacturing method of the gate stack structure 412 comprises the steps of: sequentially forming a silicon oxide layer and a first polysilicon layer (such as a doped polysilicon layer) on the substrate 400 for manufacturing the tunnel oxide layer 413 and the floating gate 414; patternizing the silicon oxide layer and the first polysilicon layer for forming a plurality of conductive wires parallel to the component isolation structure 402; coating a thin and common dielectric layer such as an oxide-nitride-oxide (ONO) dielectric layer onto the substrate 400; sequentially coating a second polysilicon layer (such as a doped polysilicon layer) and the top-cover layer 418 (such as a silicon nitride layer) for manufacturing a dielectric layer 415, control gate 416 and a top-cover layer 418 respectively.

An implant method such as an ion-implant layer is used for forming a source line 420 and a drain line 430 on both sides of the word line 410 in the substrate 400 in a path parallel to the word line 410. In FIG. 4A, the source lines 420 and the drain lines 430 are arranged alternately between the word lines 410, wherein the source line 420 is composed of a plurality of source regions 422 isolated from the component isolation structure 402 in the substrate 400, and the drain line 430 is composed of a plurality of drain regions 432 isolated from the component isolation structure 402 in the substrate 400.

In FIG. 4B, a spacer 419 is formed on both sides of a sidewall of the word line 410 and its gate stack structure 412, and the manufacturing method comprises the steps of coating a silicon nitride layer on the substrate 400 by a chemical vapor deposition (CVD) method, and performing an etch process to remove the silicon nitride layer on the word line 410 and the substrate 400 and allow the portion of the silicon nitride layer on the sidewall of the word line 410 to serve as the spacer 419. A self alignment is performed at each drain region 430 to form at least one source contact 426 and a plurality of drain contacts 434, and the contacts are electrically and separately coupled to the drain region 432, and the contacts are isolated and insulated from each other by a device such as an insulation layer 440.

With reference to FIG. 5A for a top view of a straight word line NOR type flash memory array in accordance with a preferred embodiment of the present invention, the flash memory array 501 comprises a plurality of isolation structures 502, a drain line 530, a source line 550, a discrete implant region 570, a memory unit (572A, 572B) and a plurality of word lines 510. According to the design of the mask 460 (as shown in FIG. 4A), a dopant is implanted into a portion of the source line 550 in the discrete implant region 570 to form the discrete implant regions 570 on the source line 550, and each discrete implant region 570 at least covers the region where the source line 520 is situated (refer to the source line 420 as shown in FIG. 4A), wherein the area covered by each discrete implant region 570 falls within two adjacent word lines 510 in this preferred embodiment. If the implant angle is equal to 0°, the dosage used for the implant is approximately equal to 3×10¹⁴˜1×10¹⁶ (ion/cm²), and the energy capacity is approximately equal to 5˜25(Kev). The ions used in the source line implant are arsenic (As) and/or phosphorus (P) ions. If the implant angle is equal to 20°˜30°, the dosage used for the implant is approximately equal to 5×10¹⁴˜1×10¹⁶ (ion/cm²), and the energy capacity is approximately equal to 35˜60(Kev). The ions used for the source line implant are arsenic (As) and/or phosphorus (P) ions, and a combination of implant angles can be used for performing the source implant.

With reference to FIGS. 5B and 5C for cross-sectional views of Sections A-A′ and B-B″ as depicted in FIG. 5A respectively, the figure shows a substrate 500, a word line 510, a source region 522, a drain contact 534, and an insulation layer 540. With the control of doping concentration of the discrete implant region 570, a low resistance can be achieved in the discrete implant region 570 and its adjacent drain region 532 easily by the punchthrough effect, such that a shorter channel is formed to reduce the impedance to half, and cause an electric conduction between the drain region 532 and the discrete implant region 570. Compared with the prior art, this preferred embodiment simply dopes the discrete implant region 570 into one of the regions of the source line 550 without the need of implanting the dopant onto the whole source line 550. It is noteworthy to point out that even if the discrete implant region 570 is deviated during an exposure or implant process, the word line 510 is shielded, and the implant region is limited (as shown in FIG. 5A), so that the adjacent memory units 572B will not be short circuited or failed. However, if the whole source line is doped and the source line implant is taken place before the gate stack structure is formed in accordance with the prior art, the resistance of the whole source line will become non-uniform easily once the exposure or implant deviation occurs. As a result, the adjacent memory units will have different electric properties due to the non-uniform resistance of the source.

With reference to FIG. 6A for a top view of a straight word line NOR type flash memory array in accordance with another preferred embodiment of the present invention, the discrete implant region 670 covers the area of the substrate 500 (as shown in FIG. 6B) between the two adjacent source contacts 526. With reference to FIGS. 6B and 6C for cross-sectional views of Sections A-A′ and B-B″ of FIG. 6A respectively, a step takes place after the discrete implant region 670 is formed, wherein an electrical over-erase is performed to every source contact, and this step is performed in a testing step after the memory array is completed. Since every source contact is over-erased, the two memory units connected in parallel and formed by the drain region 532 and the discrete implant region 670 form a conductive path with a low resistance (as shown in FIG. 6C), and the impedance can be reduced to half, such that an electric conduction can occur between the drain region 532 and the discrete implant region 670. Unlike the prior art, adjacent memory units 572B of the present invention will not have different electric properties caused by the non-uniform resistance of the source, if the discrete implant region 670 has an exposure or an implant deviation. In this preferred embodiment, if the implant angle is equal to 0°, the dosage used for the implant is approximately equal to 3×10¹⁴˜5×10¹⁵ (ion/cm²), and the energy capacity is approximately equal to 5˜25(Kev), wherein the ions used for the source line implant are arsenic (As) and/or phosphorus (P) ions. If the implant angle is equal to 20°˜30°, the dosage used for the implant is approximately equal to 5×10¹⁴˜8×10¹⁵(ion/cm²), and the energy capacity is approximately equal to 30˜55(Kev), wherein the ions used for the source line implant are arsenic (As) and/or phosphorus (P) ions, and a combination of implant angles can be used for implanting the source line.

While the invention has been described by means of specific embodiments, numerous modifications and variations could be made thereto by those skilled in the art without departing from the scope and spirit of the invention set forth in the claims.

What is claimed is:

1. A manufacturing method of a straight word line NOR type flash memory array, applied to a substrate, and comprising the steps of:
forming a plurality of isolation structures parallel to each other on the substrate and;
forming a plurality of gate stack structures parallel to each other on the substrate and perpendicular to the isolation structures;
forming a plurality of top-cover layers disposed on each gate stack structure to define a plurality of straight word lines;
forming a plurality of source lines and a plurality of drain lines in the substrate between adjacent gate stack structures, wherein the source lines and the drain lines are parallel to the gate stack structures, and the source lines and the drain lines are arranged alternately between the gate stack structures, and each source line has a plurality of source doped regions disposed between the isolation structures, and each drain line has a plurality of drain doped regions disposed between the isolation structures;
performing a source line implant by an arrangement of a mask to form a plurality of discrete implant regions in the substrate and parallel to the isolation structures, wherein each discrete implant region at least covers the source line;
forming a plurality of spacers on a sidewall of each gate stack structure sidewall;
forming a plurality of drain lines between adjacent spacers of each drain line; and
forming a plurality of drain contacts and at least one source contact on each drain line, wherein the contacts are isolated and insulated with each other.

2. The method of claim 1, wherein the implant angle is equal to 0°, and the dosage used for the implant is equal to 3×10¹⁴˜1×10¹⁶(ion/cm²), and the energy capacity is equal to 5˜25(Kev) in the step of performing the source line implant.

3. The method of claim 2, wherein the ions used for the implant are arsenic (As) and/or phosphorus (P) ions.

4. The method of claim 1, wherein the implant angle is equal to 20°˜30°, and the dosage used for the implant is equal to 5×10¹⁴˜1×10¹⁶(ion/cm²), and the energy capacity is equal to 35˜60(Kev) in the step of performing the source line implant.

5. The method of claim 4, wherein the ions used for the implant are arsenic (As) and/or phosphorus (P) ions.

6. The method of claim 1, wherein each discrete implant region covers an area in the substrate between two adjacent source contacts in the steps of arranging the mask and performing the source line implant, and the manufacturing method further comprises the step of performing an electrical over-erase to every source contact after the steps of arranging the mask and performing the source line implant take place.

7. The method of claim 6, wherein the implant angle is equal to 0°, and the dosage used for the implant is equal to 3×10¹⁴˜5×10¹⁵(ion/cm²), and the energy capacity is equal to 5˜25(Kev) in the step of performing the source line implant.

8. The method of claim 7, wherein the ions used for the implant are arsenic (As) and/or phosphorus (P) ions.

9. The method of claim 1, wherein the implant angle is equal to 20°˜30°, and the dosage used for the implant is equal to 5×10¹⁴˜8×10¹⁵(ion/cm²), and the energy capacity is equal to 30˜55(Kev) in the step of performing the source line implant.

10. The method of claim 9, wherein the ions used for the implant are arsenic (As) and/or phosphorus (P) ions.

11. The method of claim 1, wherein a gate stack structure of a control gate, a oxide layer/silicon nitride layer/oxide layer (ONO), and a floating gate is formed in the steps of forming the gate stack structures parallel to each other and on the substrate.
